(19) United States
(12) Patent Application Publication
(10) Pub. No.: US 2026/0107706 A1
(43) Pub. Date: Apr. 16, 2026

(54) METHOD FOR SEMICONDUCTOR MANUFACTURING

(71) Applicant: Tokyo Electron Limited, Tokyo (JP)

(72) Inventors: Tek Po Rinus Lee, Albany, NY (US); Kenichi Imakita, Albany, NY (US)

(21) Appl. No.: 18/913,135

(22) Filed: Oct. 11, 2024

(51) Int. Cl. H01L 21/285; H01L 21/02; H01L 21/324

(52) U.S. Cl. CPC H10P 14/44; H10P 14/40; H10P 14/418; H10P 95/90

(57) ABSTRACT

A method for semiconductor manufacturing includes providing a substrate into a plasma processing chamber, forming a ruthenium layer over the substrate with a physical vapor deposition using a sputtering gas including krypton or xenon, and forming a ruthenium feature from the ruthenium layer with a subtractive process. The physical vapor deposition is performed at a substrate temperature of less than 100° C.

### TECHNICAL FIELD

The present invention relates generally to semiconductor manufacturing, and, in particular embodiments, to a system and method for metal deposition.

### BACKGROUND

In the field of semiconductor manufacturing, the continuous miniaturization of integrated circuits has led to significant challenges in maintaining the performance of interconnect structures. As the dimensions of these structures decrease, particularly to 10 nm and below, the resistivity of traditional copper (Cu) interconnects increases dramatically. This increase in resistivity is due to several factors, including electron scattering at grain boundaries and surfaces, as well as the increasing proportion of the interconnect volume occupied by diffusion barriers necessary for copper features.

The search for alternative materials to replace copper in advanced interconnects has become a critical area of research and development in the semiconductor industry. Ruthenium (Ru) has emerged as a promising candidate for next-generation interconnects due to its potentially lower resistivity at small dimensions and reduced need for diffusion barriers.

However, the deposition of low-resistivity ruthenium films with desirable microstructure and electrical properties remains challenging. Conventional physical vapor deposition (PVD) techniques using argon as the sputtering gas often result in ruthenium films with higher than desired resistivity, particularly for ultra-thin films required in advanced interconnect structures.

### SUMMARY

In accordance with an embodiment, a method for semiconductor manufacturing includes: providing a substrate into a plasma processing chamber; forming a ruthenium layer over the substrate with a physical vapor deposition using a sputtering gas including krypton or xenon, the physical vapor deposition being performed at a substrate temperature of less than 100° C.; and forming a ruthenium feature from the ruthenium layer with a subtractive process.

In accordance with another embodiment, a method for metal deposition includes: providing a substrate into a physical vapor deposition (PVD) processing chamber, the PVD processing chamber including a substrate holder for supporting the substrate and multiple sputtering targets including ruthenium metal, the multiple sputtering targets being at oblique angles to a top surface of the substrate; sputtering a ruthenium metal layer onto the substrate with a plasma excitation of a noble gas including krypton or xenon at a first substrate temperature of less than 100° C.; and heat-treating the ruthenium metal layer at a second substrate temperature of 400° C. or less.

In accordance with yet another embodiment, a method for forming a conductive feature includes: providing a substrate onto a substrate holder of a plasma sputtering chamber, the substrate having a top surface including a dielectric layer; sputtering a ruthenium metal layer onto the dielectric layer using a plasma excitation of a noble gas including krypton, xenon, or radon, the dielectric layer having a temperature of less than 100° C.; heating the ruthenium metal layer to a temperature of 400° C. or less; and forming a ruthenium line from the ruthenium metal layer, the ruthenium line having a width of 10 nm or less.

It is to be understood that both the foregoing general description and the following detailed description are exemplary and explanatory only and are not restrictive of the disclosure, as claimed.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a cross-sectional view of a processing chamber, in accordance with some embodiments;

FIGS. 2-6 illustrate cross-sectional views of intermediate stages of manufacturing a semiconductor structure, in accordance with some embodiments;

FIGS. 7-10 illustrate cross-sectional views of intermediate stages of manufacturing another semiconductor structure, in accordance with some embodiments;

FIGS. 11-14 illustrate experimental results for forming low resistivity ruthenium films with sputtering processes, in accordance with some embodiments;

FIG. 15 illustrates a process flow chart diagram of a method for forming a low resistivity ruthenium film, in accordance with some embodiments;

FIG. 16 illustrates a process flow chart diagram of a method for semiconductor manufacturing, in accordance with some embodiments;

FIG. 17 illustrates a process flow chart diagram of a method for metal deposition, in accordance with some embodiments; and FIG. 18 illustrates a process flow chart diagram of a method for forming a conductive feature, in accordance with some embodiments.

Corresponding numerals and symbols in the different figures generally refer to corresponding parts unless otherwise indicated. The figures are drawn to clearly illustrate the relevant aspects of the embodiments and are not necessarily drawn to scale. The edges of features drawn in the figures do not necessarily indicate the termination of the extent of the feature.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope.

There is a need for improved methods of depositing ruthenium films with lower resistivity, larger grain sizes, and better overall electrical performance for use in advanced semiconductor devices. The use of ruthenium may allow for formation of conductive features (e.g., lines or vias) without an intervening diffusion barrier on the sidewalls of the features. The absence of a diffusion barrier may enable an increased volume of ruthenium to be used, thereby decreasing feature resistivity.

According to one or more embodiments of the present disclosure, this application relates to methods for depositing low-resistivity ruthenium films using physical vapor deposition (PVD) techniques. These methods utilize alternative sputtering gases, such as krypton (Kr) or xenon (Xe), in combination with various process conditions to achieve ruthenium films with improved electrical and microstructural properties, such as lower resistivity and larger grain sizes.

Embodiments of the present disclosure include methods for depositing ruthenium layers using PVD with, for example, krypton or xenon as the sputtering gas at substrate temperatures below 100° C. These low-temperature deposition conditions, combined with the use of heavier noble gases, may result in ruthenium films with larger grain sizes and lower resistivity compared to conventional argon-sputtered films. Embodiments of the present disclosure further include post-deposition heat treatment steps, performed at temperatures up to or around 400° C., which can further enhance the properties of the deposited ruthenium films. These methods are particularly advantageous for creating ultra-thin ruthenium features, such as interconnect lines with widths of 10 nm or less. Furthermore, embodiments of the disclosure include modifications to existing PVD systems, such as the incorporation of additional gas lines to enable mixed-gas sputtering, which may provide greater flexibility and control over the deposition process.

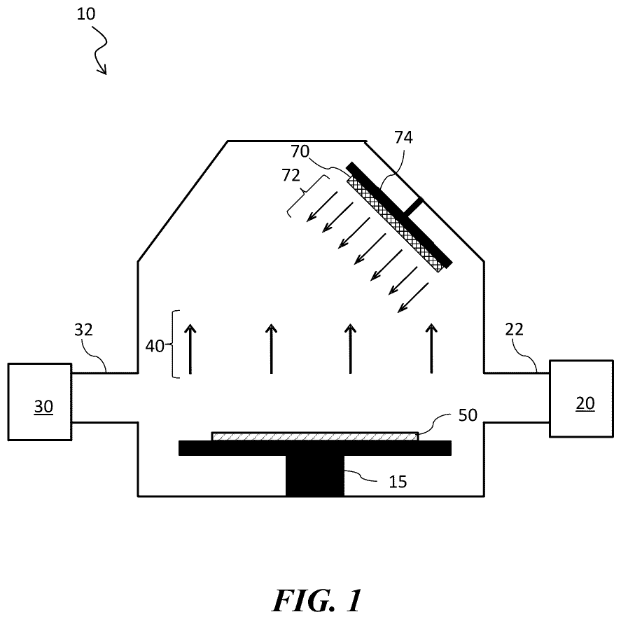

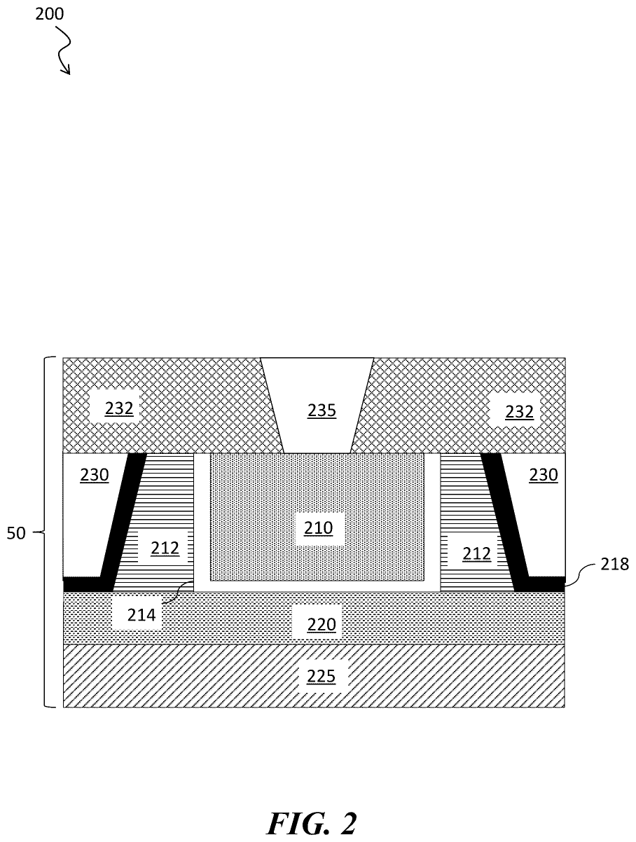

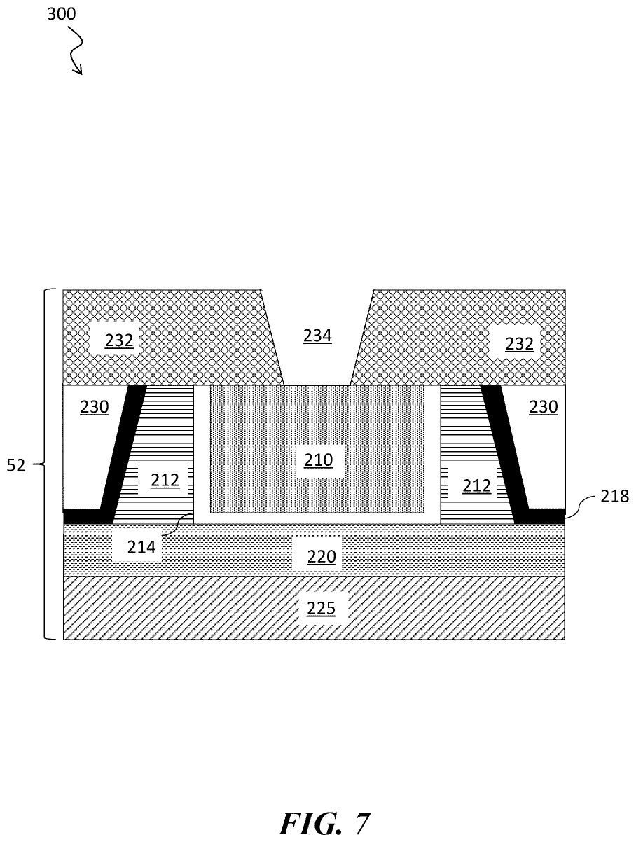

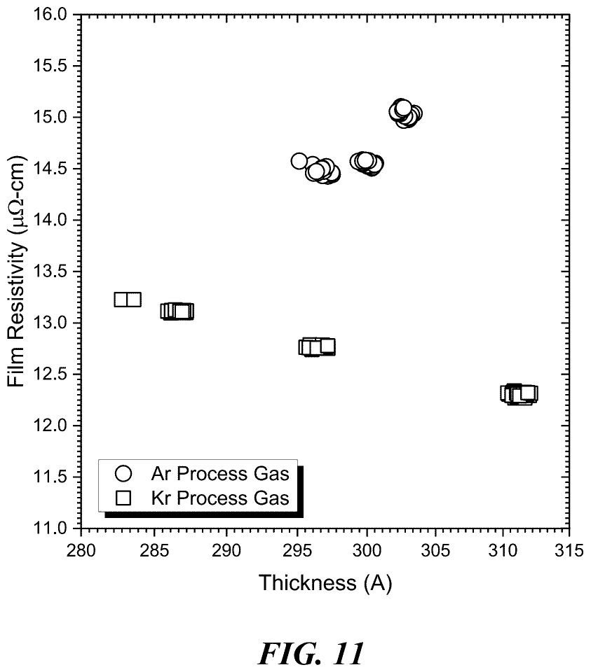

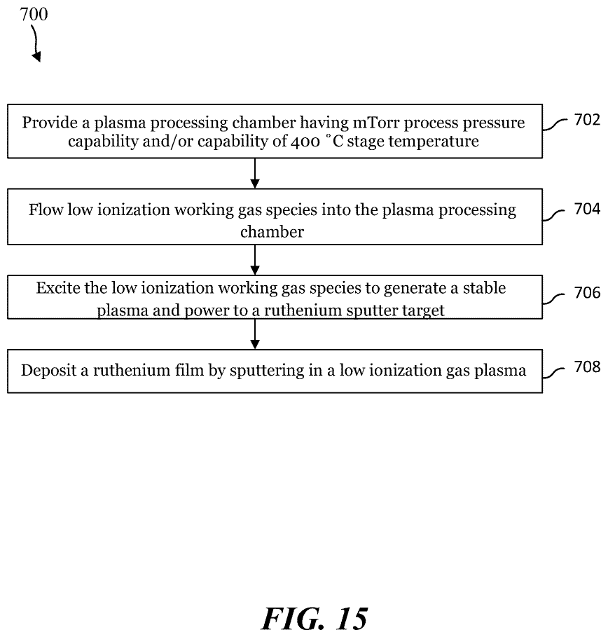

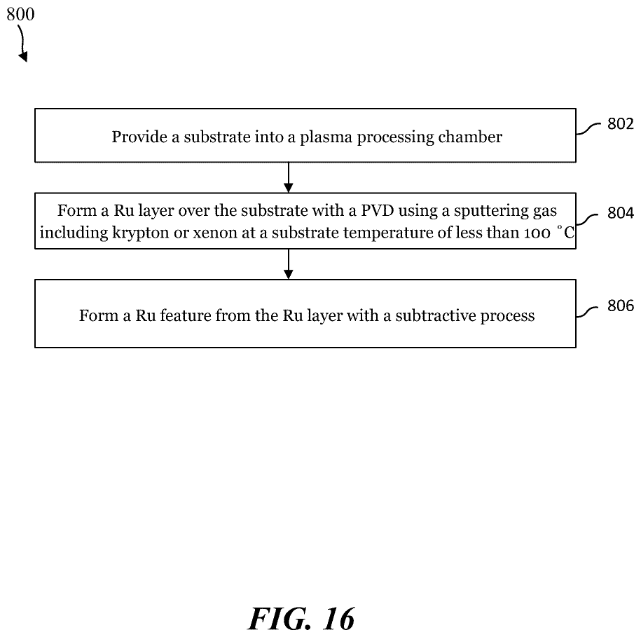

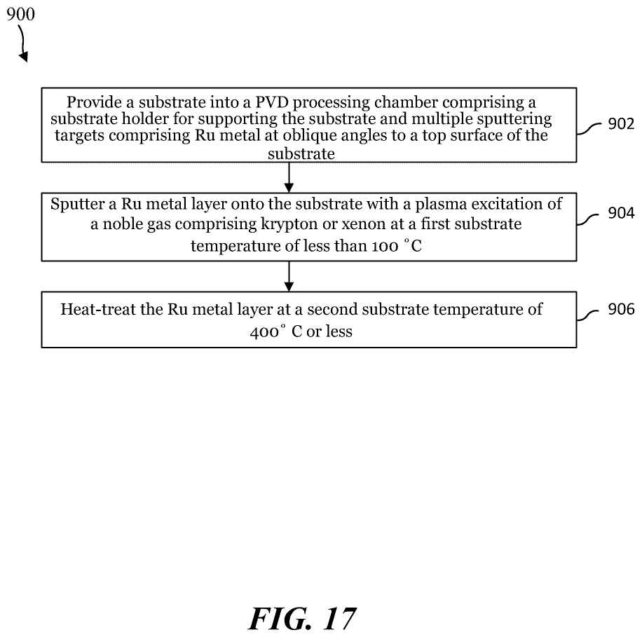

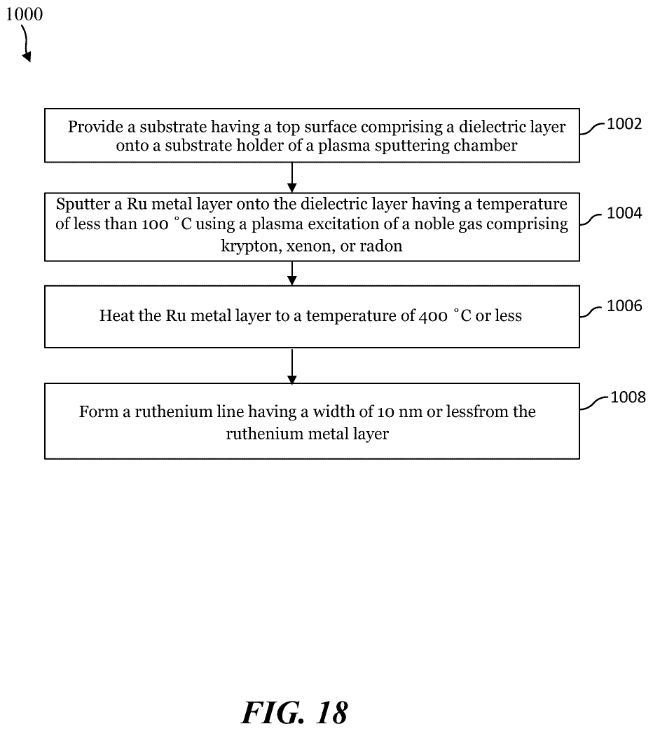

Embodiments of the disclosure are described in the context of the accompanying drawings. An embodiment of a processing chamber for performing a physical vapor deposition (PVD) process will be described using FIG. 1. An embodiment of a method for manufacturing a semiconductor structure will be described using FIGS. 2 through 6. An embodiment of a method for manufacturing another semiconductor structure will be described using FIGS. 7 through 10. Experimental results for forming low resistivity ruthenium films with sputtering processes will be described using FIGS. 11-14. An embodiment of a method for forming a low resistivity ruthenium film will be described using FIG. 15. An embodiment of a method for semiconductor manufacturing will be described using FIG. 16. An embodiment of a method for metal deposition will be described using FIG. 17. An embodiment of a method for forming a conductive feature will be described using FIG. 18.

FIG. 1 illustrates a cross-sectional view of an example processing chamber 10 (also referred to as a plasma processing chamber or a physical vapor deposition processing chamber) for performing a physical vapor deposition (PVD) of a ruthenium layer over a substrate 50, in accordance with some embodiments. The processing chamber 10 is configured for physical vapor deposition (PVD). In some embodiments, the processing chamber 10 is configured to perform high-power impulse magnetron sputtering (HIPIMS) or high-power pulsed magnetron sputtering.

The processing chamber 10 includes a chuck 15 for holding a substrate 50. The chuck 15 is configured to hold a substrate 50 (e.g., a semiconductor wafer that may have front end of the line (FEOL) structures including active devices formed on a top surface) inside the processing chamber 10 to process a major surface of the substrate 50. For example, the chuck 15 may be an electrostatic chuck including a bottom electrode or anode (not illustrated). In some embodiments, the chuck 15 is configured to rotate the substrate 50 during a deposition process, which may increase uniformity of deposition.

The processing chamber 10 is coupled to a vacuum pump 20 through an outlet 22. The vacuum pump 20 is used to evacuate the processing chamber 10 to a sufficiently low pressure for performing PVD, e.g. a pressure less than 1 mTorr. In some embodiments, the processing chamber pressure depends on the flow rate of the sputtering gas and is around, e.g., 0.5 mTorr. The vacuum pump 20 may be any suitable vacuum pump, e.g. a turbomolecular pump.

A gas source 30 (e.g., one or more gas cylinders) is coupled to the processing chamber 10 through an inlet 32. The gas source 30 provides a sputtering gas to the processing chamber 10. The sputtering gas may be an inert gas such as krypton, xenon, radon, neon, the like, or a combination thereof. In some embodiments, the gas source 30 comprises respective gas cylinders of krypton, xenon, radon, and neon, which can be configured to be supplied to the processing chamber 10 in any suitable combination. Use of one or more low ionization gases such as krypton, xenon, or radon may be advantageous for sustaining a low process pressure environment while still being able to ignite a plasma.

In various embodiments, the sputtering gas is a noble gas that is free of argon, such as krypton, xenon, radon, or a combination thereof. In some embodiments, the gas source 30 is configured to supply an argon-free sputtering gas consisting essentially of krypton. In some embodiments, the gas source 30 is configured to supply an argon-free sputtering gas consisting essentially of xenon. In some embodiments, the gas source 30 is configured to supply an argon-free sputtering gas consisting essentially of a combination of krypton and xenon. In some embodiments, the gas source 30 is configured to supply a sputtering gas consisting essentially of a combination of argon and one or more other noble gas(es). In some embodiments, the gas source 30 is configured to supply a sputtering gas consisting essentially of a combination of krypton and argon. In some embodiments, the gas source 30 is configured to supply a sputtering gas consisting essentially of xenon and argon.

A target 70 is mounted on a top cathode 74 of the processing chamber 10. The target 70 (also referred to as a sputtering target) is a source of the material to be deposited by physical vapor deposition over the substrate 50. For example, in some embodiments, the target 70 is a sheet of ruthenium (Ru) metal. Although one target 70 of ruthenium metal is illustrated in FIG. 1, any suitable number of targets may be present and mounted on respective cathodes.

In some embodiments, the target 70 is mounted at an oblique angle to the chuck 15 and to any substrate 50 mounted on the chuck 15. In other embodiments, the target 70 is in a plane parallel to a plane of the top surface of the substrate 50. In various embodiments, multiple targets 70 are present and are mounted at oblique angles to top surfaces of the chuck 15 and substrate 50, in planes parallel to a plane of the top surface of the substrate 50, or a combination thereof.

The substrate 50 is transported to the processing chamber 10 and mounted on the chuck 15. In some embodiments, the substrate 50 is cooled to a temperature less than 100° C., such as less than 50° C., prior to being installed in the processing chamber 10. In some embodiments, the processing chamber 10 is operated at a process temperature less than 100° C., or less than 50° C., such as room temperature (e.g., about 25° C.), during deposition processes.

Once the substrate 50 is installed and the processing chamber 10 and substrate 50 are brought to a suitable pressure (such as 0.1 mTorr to 100 mTorr) and the substrate 50 is brought to a suitable substrate temperature (e.g., less than 100° C., or less than 50° C., such as room temperature (e.g., about 25° C.)), the sputtering gas is flowed from the gas source 30 through the inlet 32 into the processing chamber 10. Performing the sputtering in a low pressure environment, is advantageous for forming larger grains and/or a denser film, which may provide lower resistivity.

The use of low ionization process gases such as krypton, xenon, or radon offers several significant advantages for ruthenium deposition via physical vapor deposition (PVD), particularly for advanced interconnect applications. Firstly, these gases allow for operation at lower process pressures compared to conventional argon sputtering. The lower pressure environment results in fewer collisions between the sputtered ruthenium atoms and gas molecules as they travel from the target 70 to the substrate 50. This allows the ruthenium atoms to retain more of their initial kinetic energy when they arrive at the deposition surface. The higher energy of the arriving atoms promotes increased surface mobility, enabling the formation of larger grains and denser films.

Experimental data demonstrates that using krypton as the sputtering gas results in ruthenium films with significantly lower resistivity compared to argon-sputtered films. Analysis has shown this resistivity reduction correlates with an increase in average grain size from about 18 nm with argon to 22 nm with krypton. The larger grains reduce electron scattering at grain boundaries, contributing to the observed resistivity decrease. Partially or fully replacing argon as the sputtering gas with a low ionization gas such as krypton, xenon, or radon would not be obvious to one of ordinary skill in the art without the motivation of this experimental data, as argon is generally less expensive and more easily accessible from atmospheric extraction than other noble gases such as krypton, xenon, or radon.

Furthermore, the benefits of low ionization gas sputtering extend to patterned structures as well. Tests on 10 nm wide ruthenium lines show lower line resistivity when deposited using krypton compared to argon. This is useful for advanced interconnects, where maintaining low resistivity at narrow linewidths is advantageous for overall device performance.

The ability to operate at lower pressures while maintaining a stable plasma also provides greater flexibility in optimizing other process parameters. This can potentially enable further enhancements to film properties beyond what is possible with conventional argon sputtering. Additionally, the concept is compatible with other hardware modifications being explored, such as the use of high-power impulse magnetron sputtering (HIPIMS) to further increase the kinetic energy of sputtered atoms.

In some embodiments, the sputtering gas is flowed at a rate in a range of 10 sccm to 100 sccm. The sputtering gas is excited to a stable plasma state with a plasma excitation to produce ions 40 (e.g., Kr⁺ or Xe+ ions). The ions 40 of the sputtering gas may be directed to bombard the target 70 by applying an electric field between the top cathode 74 and the bottom electrode of the chuck 15. In some embodiments, the electric field is generated with a DC power (as measured at the power source) in a range of 0.1 KW to 1.5 KW.

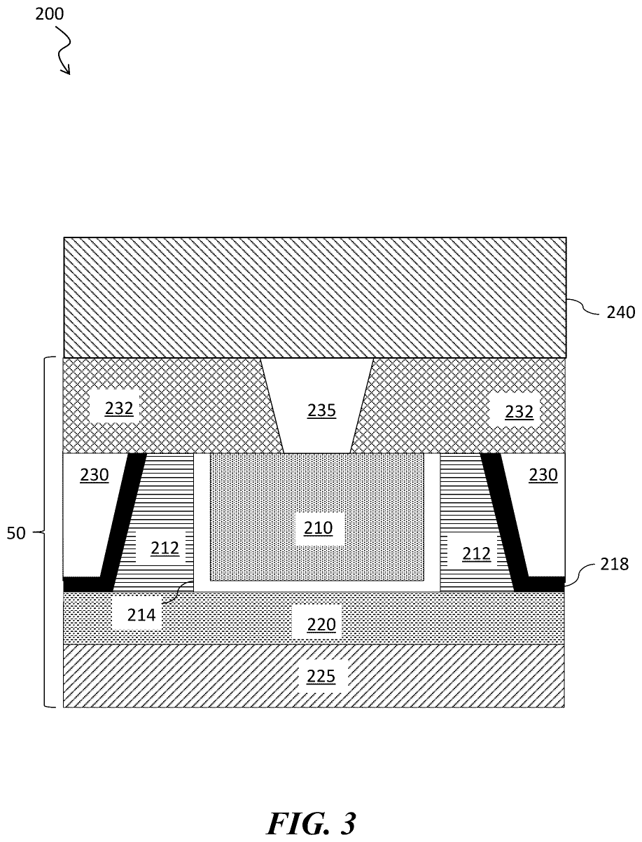

The ions 40 bombard the target 70, ejecting atoms 72 of ruthenium metal from the target 70. The atoms 72 are deposited in a sputtered layer (see below, FIG. 3) of ruthenium metal over the substrate 50. The deposition of the sputtered layer may be performed for a duration in a range of 10 seconds or more, such as 10 seconds to 5000 seconds, which may occur over one or more rotations of the substrate 50 by the chuck 15. In some embodiments, the sputtered layer is formed to a thickness in a range of 200 Å to 800 Å.

After forming the sputtered layer, a heat treatment may be performed on the sputtered layer by heating the substrate 50 to a substrate temperature of 400° C. or less, such as a temperature in a range of 100° C. to 400° C. This may be advantageous for reducing surface oxidation of the sputtered layer. In various embodiments, the heat treatment is performed with an anneal, such as with a suitable gas such as hydrogen (H²) or the like. The heat treatment may also be performed in a vacuum. For example, in other embodiments, the heat treatment is performed with a heater element in the chuck 15.

FIGS. 2 through 6 illustrate intermediate stages of manufacturing of a semiconductor structure 200 in a cross-sectional view, in accordance with some embodiments. The semiconductor structure 200 includes a sputtered layer that is formed and patterned with a subtractive process.

FIG. 2 illustrates an example substrate 50, in accordance with some embodiments. In various embodiments, the substrate 50 may be a part of, or include, a semiconductor device (e.g. one or more transistors), and may have undergone a number of steps of processing following, for example, a conventional process. The substrate 50 accordingly may comprise layers of semiconductors useful in various microelectronics. For example, the semiconductor structure 200 may comprise the substrate 50 in which various device regions are formed.

As illustrated in FIG. 2, the example substrate 50 includes a semiconductor substrate 225, a shallow trench isolation (STI) region 220, a metal gate 210, a high-k gate dielectric 214, a pair of source/drain spacers 212, a source/drain contact etch-stop layer (CESL) 218, a first interlayer dielectric (ILD) 230, a second ILD 232 (also referred to as a dielectric layer), and a contact 235.

In various embodiments, the semiconductor substrate 225 is a silicon wafer (e.g., a bulk crystalline silicon wafer), or a silicon-on-insulator (SOI) wafer. In certain embodiments, the semiconductor substrate 225 comprises silicon germanium, silicon carbide, gallium arsenide, gallium nitride, or other compound semiconductors. In other embodiments, the semiconductor substrate 225 comprises heterogeneous layers such as silicon germanium on silicon, gallium nitride on silicon, silicon carbon on silicon, as well layers of silicon on a silicon or SOI substrate. In various embodiments, the semiconductor substrate 225 is patterned or embedded in other components of the semiconductor device.

A gate structure of a transistor (e.g., a FinFET) is over the semiconductor substrate 225. The gate structure comprises a metal gate 210 (e.g., a multilayer metal stack comprising Ta, TaN, TiN, W, the like, or a combination thereof) and a gate dielectric 214 (e.g., a high-k gate dielectric comprising HfO₂, Al₂O₃, the like, or a combination thereof) inlaid within a recess formed earlier between a pair of source/drain spacers 212 (e.g., SiOxNy spacers). As illustrated in FIG. 2, the metal gate 210 and the gate dielectric 214 are a portion of the metal gate structure and extend over a shallow trench isolation (STI) region 220 in recesses between semiconductor fins formed earlier, for example, by etching the semiconductor substrate 225. The semiconductor fins are not illustrated, being located along planes parallel to the plane of the cross-sectional view in FIG. 2. Source/drain regions (not illustrated) may be present in or on portions of the semiconductor fins adjacent to the gate structure.

The first ILD 230 is over the STI region 220 and the semiconductor substrate 225 and is adjacent to sidewalls of the source/drain spacers 212. The first ILD 230 comprises one or more insulators such as SiO₂ or a silicon oxide based low-k dielectric (e.g., porous oxides, fluorosilicate glass (FSG), and organosilicate glass (OSG)). In some embodiments, a source/drain contact etch-stop layer (CESL) 218 (e.g., a Si₃N₄ layer) lines the bottom surface of the first ILD 230.

A second ILD 232 is over the first ILD 230, the gate structure (including the metal gate 210 and the gate dielectric 214), and the source/drain spacers 212. The second ILD 232 may include similar materials as the first ILD 230 (see above). In some embodiments, the second ILD 232 includes a bottom layer that is an etch stop layer (ESL) that comprises a dielectric such as Si₃N₄, SiOₓN_{y}, SiC, or SiCN (not shown). A contact 235 extends through the second ILD 232 and physically and electrically couples with the metal gate 210. The contact 235 comprises a conductive material such as a metal (e.g., copper (Cu), tungsten (W), cobalt (Co), the like, or a combination thereof) and is formed with a suitable process, such as a damascene process. Additionally, in some embodiments, a conductive ESL (not shown) comprising, for example, TiN or TaN is formed over the second ILD 232 and the contact 235 before subsequent layers (e.g., the sputtered layer 240; see below, FIG. 3) are deposited.

The substrate 50 is a non-limiting example and is described above for illustrative purposes. Any suitable substrate 50 with any suitable composition or arrangement of features may be used for the manufacturing of a semiconductor structure 200 that includes a conductive layer (see below, FIG. 3) formed on the substrate 50, and should be understood to be within the scope of the disclosed embodiments.

FIG. 3, following from FIG. 2, illustrates the formation of a sputtered layer 240 over the substrate 50. In various embodiments, the substrate 50 is provided into a processing chamber (e.g., the processing chamber 10; see above, FIG. 1). The sputtered layer 240 is then formed over the substrate 50 using a physical vapor deposition (PVD) process to sputter ruthenium onto the top surface of the substrate 50. The PVD process to form the sputtered layer 240 may be performed as described above with respect to FIG. 1, and the details are not repeated herein. In various embodiments, the sputtered layer 240 comprises ruthenium, and may also be referred to as a ruthenium layer or a ruthenium metal layer.

In some embodiments, the sputtered layer 240 is formed over the second ILD 232 and the contact 235 in the example illustrated by FIG. 3. In other embodiments, the second ILD 232 and the contact 235 are not present and the sputtered layer 240 is formed directly on the gate structure including the metal gate 210 and the gate dielectric 214. The sputtered layer 240 may be formed over any suitable substrate 50, and all such substrates are within the scope of the disclosed embodiments.

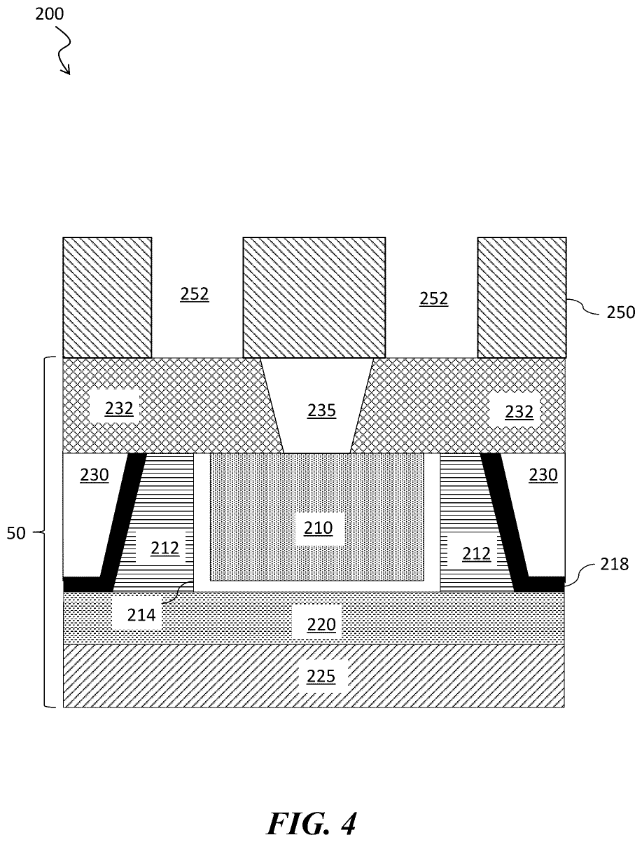

Next, FIG. 4 illustrates a subtractive process in which the sputtered layer 240 is patterned to form conductive features 250, in accordance with some embodiments. The conductive features 250 (e.g., conductive lines) may form electrical connections in an interconnect structure, such as for back end of the line (BEOL) applications. In some embodiments, the conductive features 110 have widths (also referred to as critical dimensions) in a range of 5 nm to 15 nm, or less than 10 nm. In various embodiments, the conductive features 250 comprise ruthenium and are also referred to as ruthenium features. In some embodiments, the conductive features 250 are metal lines and are also referred to as ruthenium metal lines or ruthenium lines.

As an example of forming the conductive features 250, a patterned photoresist layer (not illustrated) is formed over the top surface of the sputtered layer 240 using a photomask with a pattern designed for, e.g., conductive lines. Next, openings 252 are etched using the patterned photoresist layer as an etch mask. The etching may be performed using a suitable anisotropic etch technique, for example, a reactive ion etch (RIE) process using fluorine chemistry. However, any suitable etching process may be used. The etch may be chosen to be selective with the material underlying the conductive features 110, e.g. dielectric material the second ILD 232. In some embodiments, the sputtered layer 240 is formed over another conductive material (e.g., a metal such as tungsten, cobalt, or copper, such as in the contact 235), and the etch process is selective with the conductive material underlying the sputtered layer 240.

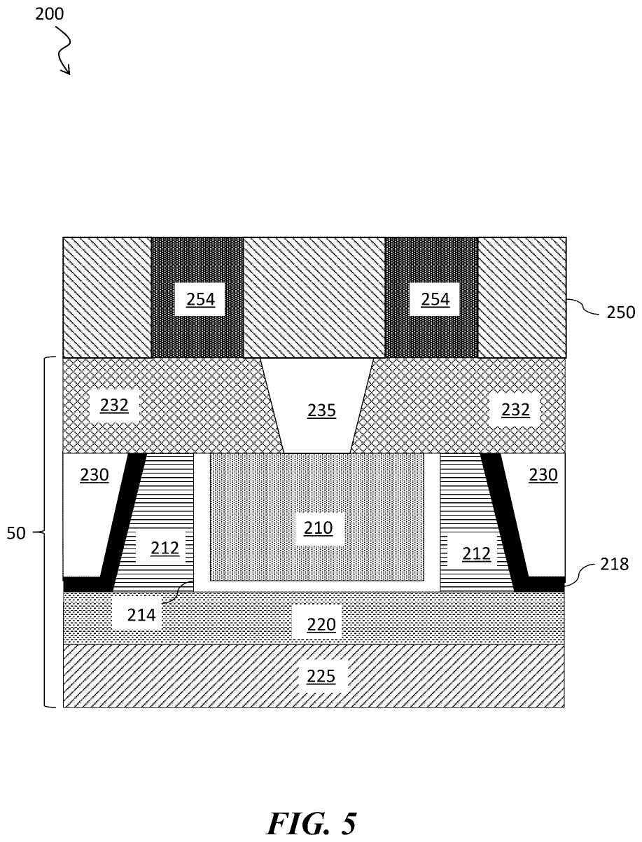

Next, in FIG. 5, a first intermetal dielectric (IMD) 254 is formed over the conductive features 250 and fills the openings 252 (see above, FIG. 4), in accordance with some embodiments. The IMD 254 comprises an insulating material such as SiO₂ or a silicon oxide based low-k dielectric (e.g., porous oxides, fluorosilicate glass (FSG), and orthosilicate glass (OSG)), similar to the materials of the first ILD 230 and the second ILD 232 described above with respect to FIG. 2. The IMD 254 may be formed with a suitable process such as CVD or the like. In some embodiments, an excess portion of the IMD 254 above the conductive features 250 is removed with a suitable etchback technique, for example, a chemical mechanical polish (CMP). In some embodiments, respective top portions of the conductive features 250 are also removed.

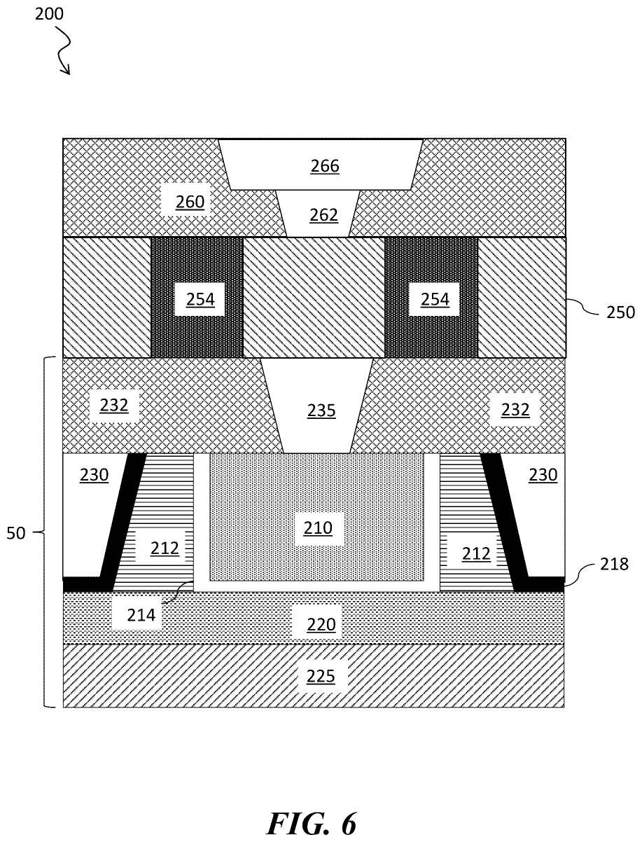

In FIG. 6, following from FIG. 5, an interconnect layer is formed over the conductive features 250 and the IMD 254, in accordance with some embodiments. The interconnect layer includes an IMD 260 with a conductive via 262 and a conductive line 266 formed therein. The IMD 260 may be formed using similar methods and materials as described above for the IMD 254 with respect to FIG. 5. The conductive via 262 connects the conductive line 266 to a portion of the conductive feature 250 disposed directly below the conductive line 266. The conductive via 262 and the conductive line 266 may be formed with, for example, a conventional dual-damascene process using a conductive material such as copper or the like. As known by a person skilled in the art, the dual-damascene flow comprises patterning openings (e.g., holes for conductive vias 262 and trenches for conductive lines 266) in the IMD 260 using a via-first or a trench-first patterning sequence, depositing a conformal barrier metal (e.g., TiN or TaN) liner, filling the openings with metal (e.g., using Cu electroplating), and removing all excess conductive material from the top surface of the IMD 260 using a planarization process such as chemical mechanical planarization (CMP), thereby forming the conductive vias 262 and conductive lines 266 inlaid in the IMD 260. However, any suitable process can be used to form the conductive via 262 and the conductive line 266, such as a process comprising a physical vapor deposition of ruthenium and a subsequent etch using similar materials and methods as the formation of the conductive features 250 as described above with respect to FIGS. 3-4, and all such processes and resulting structures are within the scope of the disclosed embodiments.

The interconnect layer including the IMD 260 with the conductive via 262 and the conductive line 266 is included as a non-limiting example. Any suitable interconnect layer may be formed over the conductive features 250 and IMD 254 and is within the scope of the disclosed embodiments. For example, an additional conductive layer similar to the sputtered layer 240 (see above, FIG. 3) may be formed over the conductive features 250 and IMD 254 and subsequently patterned to form additional conductive features, with spaces between the conductive features subsequently filled by an IMD.

FIGS. 7 through 10 illustrate intermediate stages of manufacturing of another semiconductor structure 300 in a cross-sectional view, in accordance with some embodiments. The semiconductor structure 300 includes a sputtered layer that is formed and patterned with a semi-damascene process.

FIG. 7 illustrates a substrate 52 that is similar to the substrate 50 as described above with respect to FIG. 2 but without the contact 235 formed through the second ILD 232. An opening 234 is formed through the second ILD 232 to expose a top surface of the metal gate 210. The opening 234 may be formed with a suitable lithographic patterning process. In some embodiments, the opening 234 has tapered sidewalls and a trapezoidal profile in a cross-sectional view.

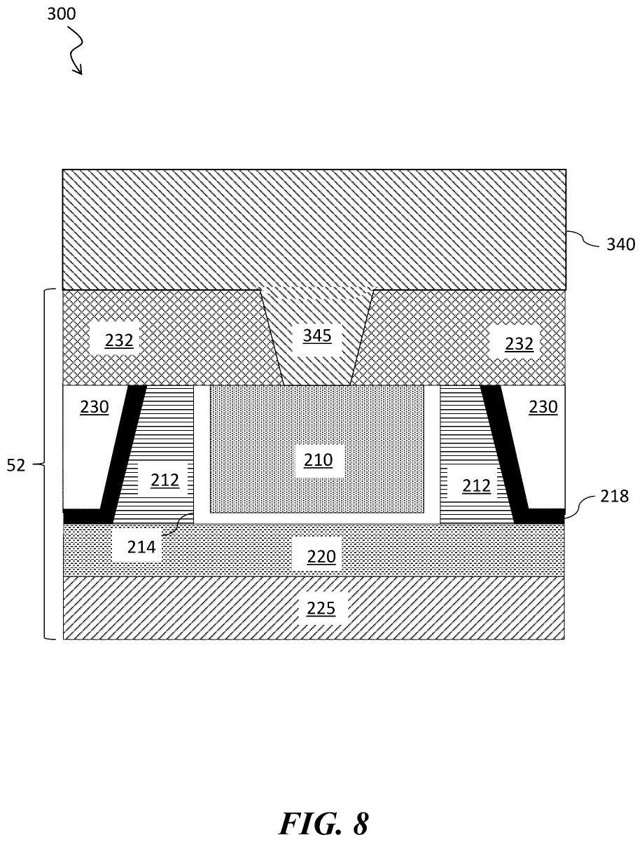

In FIG. 8, following from FIG. 7, a sputtered layer 340 is formed over the second ILD 232 and fills the opening 234 (see above, FIG. 7), physically contacting the top surface of the metal gate 210. The sputtered layer 340 may be formed using similar methods and materials as the sputtered layer 240 as described above with respect to FIG. 3. As illustrated in FIG. 8, a bottom portion of the sputtered layer 340 fills the opening 234 to form a conductive via 345.

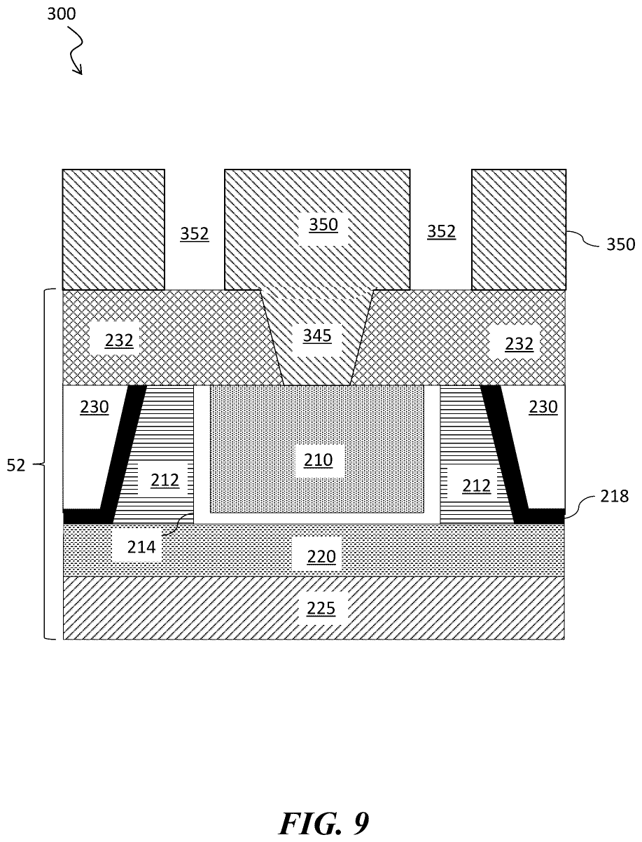

Next, in FIG. 9, the sputtered layer 340 is patterned to form conductive features 350 separated by air gaps 352. The sputtered layer 340 may be patterned by a similar process as the sputtered layer 240 as described above with respect to FIG. 4, and the details are not repeated herein. As illustrated in FIG. 9, the middle conductive feature 350 comprises a conductive via 345 that extends through the second ILD 232 to contact the metal gate 210 and an upper line portion above the second ILD 232. As such, the conductive features 350 are formed with a semi-damascene process.

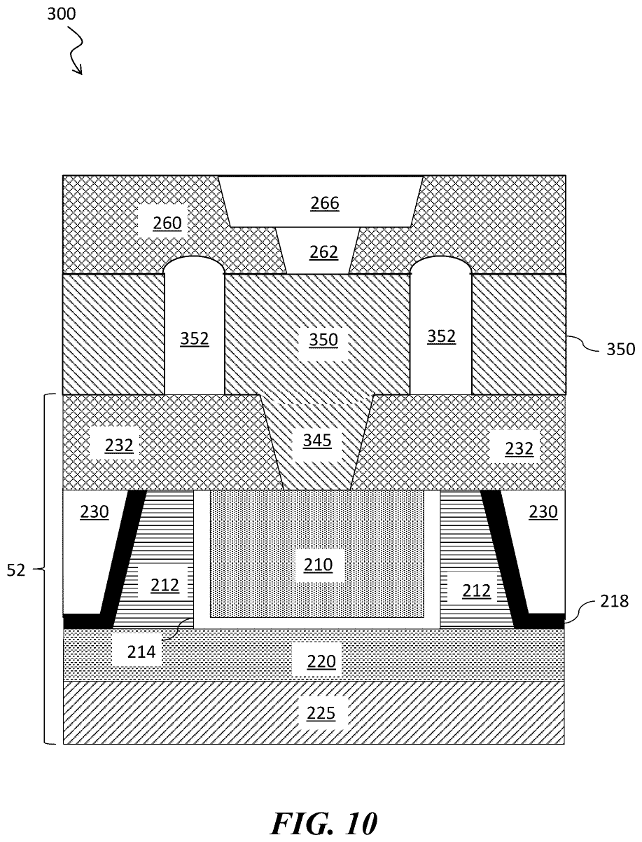

In FIG. 10, following from FIG. 9, an interconnect layer is formed over the conductive features 350 and the air gaps 352, in accordance with some embodiments. The interconnect layer includes an IMD 260 with a conductive via 262 and a conductive line 266 formed therein. The conductive via 262 connects the conductive line 266 to a portion of the conductive feature 350 disposed directly below the conductive line 266. The IMD 260, conductive via 262, and conductive line 266 may be formed using similar methods and materials as described above with respect to FIG. 6, and the details are not repeated herein.

The air gaps 352 may be sealed by the IMD 260 and may contain air or other gases. The air gaps 352 being disposed between adjacent conductive features 350 that comprise ruthenium metal may reduce the resistance of the conductive features 350, thus increasing device performance.

FIG. 11 illustrates a graph of experimental results showing the relationship between film resistivity and thickness for ruthenium films deposited using krypton and argon as process gases. The graph presents experimental data points for both gas conditions, allowing for a direct comparison of the resistivity characteristics.

The horizontal axis of the graph represents the film thickness, measured in Angstroms (A). The thickness range displayed extends from approximately 280 Å to 315 Å. This relatively narrow range focuses on the thickness regime relevant for advanced interconnect applications. The vertical axis illustrates the film resistivity, measured in micro-ohm-centimeters (μΩ-cm). The resistivity values on this axis range from about 11.0 μΩ-cm to 16.0 μΩ-cm, capturing the variation observed across different deposition conditions and film thicknesses.

Two distinct sets of data points are plotted on the graph for an argon process gas and a krypton process gas. Argon process gas data points are represented by open circles. The argon-sputtered films show resistivity values primarily clustered between 14.0 μΩ-cm and 15.5 μΩ-cm. The thickness range for these films spans a range from 290 Å to 305 Å.

Krypton process gas data points are represented by open squares. The krypton-sputtered films exhibit consistently lower resistivity values than the argon-sputtered films, ranging from approximately 11.5 μΩ-cm to 13.5 μΩ-cm. The thickness range for these films is broader than for the argon-sputtered films, extending from about 280 Å to 315 Å, illustrating that the lower resistivity of the krypton-sputtered films is consistent across a wide thickness range.

A clear separation is visible between the two data sets, with the krypton-sputtered films showing lower resistivity across the entire thickness range studied. This separation demonstrates the significant impact of using krypton as the sputtering gas on reducing film resistivity. For both gas conditions, there appears to be a slight trend of decreasing resistivity with increasing film thickness. This trend is more pronounced for the krypton-sputtered films, particularly in the thickness range from 280 Å to 300 Å.

As such, FIG. 11 illustrates the resistivity advantages achieved by using krypton as the sputtering gas for ruthenium film deposition. The lower resistivity values obtained with krypton sputtering align with the goal of improving the electrical performance of ruthenium interconnects in advanced semiconductor devices.

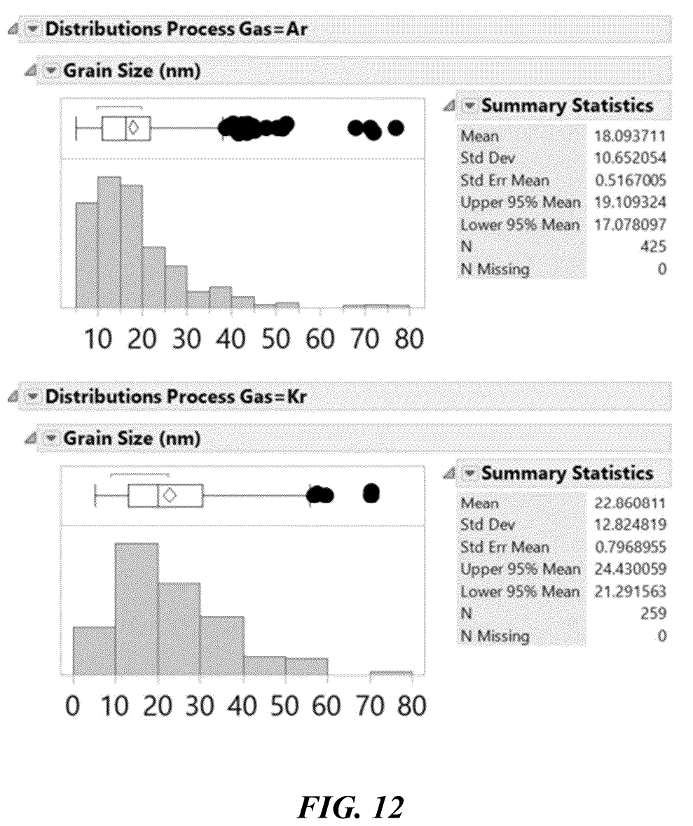

FIG. 12 illustrates a comparative analysis of experimental results of grain size distributions for ruthenium blanket films deposited using krypton and argon as process gases. FIG. 12 consists of two vertically arranged histograms, each representing the grain size distribution for a specific sputtering gas.

The top histogram of FIG. 12 illustrates the grain size distribution for ruthenium films deposited using argon as the process gas. The vertical axis shows the frequency or count of grains within each size range. The distribution appears to be roughly normal, with a slight positive skew. The peak of the distribution occurs around 15-20 nm. A text annotation on the graph indicates that the mean grain size for argon-sputtered films is 18 nm.

The bottom histogram of FIG. 12 illustrates the grain size distribution for ruthenium films deposited using krypton as the process gas. The horizontal and vertical axes are the same as the top histogram. The distribution for krypton-sputtered films also appears approximately normal with a slight positive skew, but it is visibly shifted towards larger grain sizes compared to the argon distribution. The peak of this distribution occurs around 20-25 nm. A text annotation on this graph states that the mean grain size for krypton-sputtered films is 22 nm. As such, the krypton-sputtered film shows a clear shift towards larger grain sizes compared to the argon-sputtered film. The mean grain size increases from 18 nm with argon to 22 nm with krypton, representing a significant 22% increase.

Both distributions maintain a similar overall shape, suggesting that the fundamental grain formation process is consistent between the two sputtering gases, but with krypton promoting larger grain growth. Both distributions show grains ranging from very small (near 0 nm) to quite large (around 40-45 nm), indicating a diverse mix of grain sizes in both films. The krypton distribution appears to have a slightly lower and broader peak compared to the argon distribution, which could indicate a more even distribution of grain sizes.

FIG. 12 provides experimental evidence of the impact of using krypton as the sputtering gas on the microstructure of deposited ruthenium films. The larger average grain size observed with krypton sputtering correlates with the lower resistivity values illustrated above in FIG. 11 for krypton-sputtered ruthenium blanket films. This may support a mechanism of resistivity reduction through increased grain size.

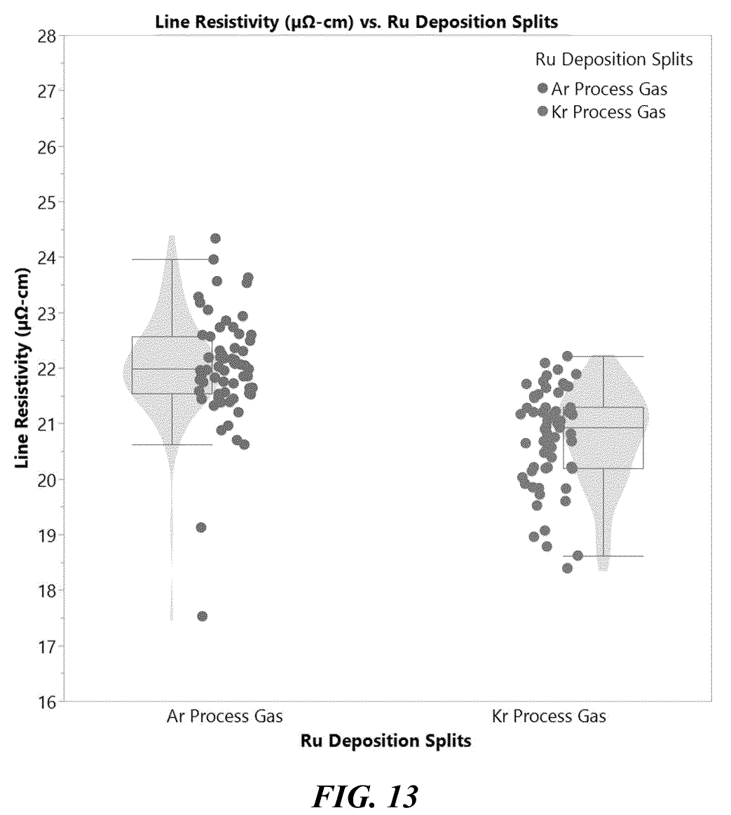

FIG. 13 illustrates a comparison of line resistivity measurements for ruthenium interconnects deposited using krypton and argon. FIG. 13 illustrates the impact of the sputtering gas on the electrical performance of narrow ruthenium lines, such as those with a width of 10 nm. The left and right data points of FIG. 13 each represent a different deposition condition or “split”. The left data points represent the line resistivity for ruthenium lines deposited using argon as the process gas. The right data points represent the line resistivity for ruthenium lines deposited using krypton as the process gas.

The vertical axis of the chart shows the line resistivity, measured in micro-ohm centimeters (μΩ-cm). The scale of this axis is not explicitly provided in the image, but the relative heights of the bars indicate a significant difference in resistivity between the two deposition conditions.

The krypton-sputtered ruthenium lines on the right show noticeably lower resistivity compared to the argon-sputtered lines on the left. The magnitude of this reduction appears to be substantial, such as in the range of 15-25%. The trend observed in FIG. 13 aligns with the results presented in the blanket film resistivity data (see above, FIG. 11), where krypton sputtering also resulted in lower resistivity. The measurements illustrated in FIG. 13 are for 10 nm wide lines, which is significant as it demonstrates the benefit of krypton sputtering at dimensions relevant to advanced interconnect technologies.

As such, FIG. 13 illustrates advantages of using krypton as the sputtering gas for ruthenium deposition in the context of narrow interconnect lines. The lower line resistivity achieved with krypton sputtering demonstrates that the advantages observed in blanket films may translate effectively to patterned structures, which is crucial for practical application in semiconductor devices. This result supports the potential of krypton sputtering as a method to address the conductivity challenges in scaled interconnects for advanced technology nodes.

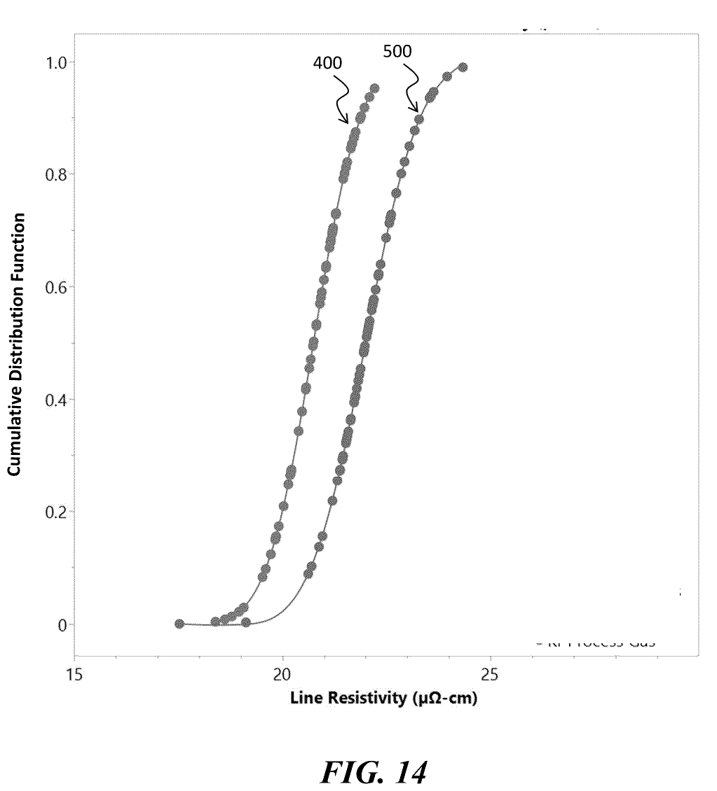

FIG. 14 illustrates experimental results of cumulative distribution function (CDF) versus line resistivity for ruthenium interconnect lines (e.g., lines with 10 nm widths) deposited using krypton and argon. The horizontal axis of the graph represents the line resistivity, measured in micro-ohm centimeters (μΩ-cm). The vertical axis represents the cumulative probability, ranging from 0 to 1 (or 0% to 100%). This axis shows the proportion of measurements that fall at or below a given resistivity value.

Curve 400 represents the CDF for ruthenium lines deposited using krypton as the process gas, and curve 500 represents the CDF for ruthenium lines deposited using argon as the process gas. Curve 400 (krypton) is shifted to the left of curve 500 (argon), indicating that krypton-sputtered lines generally have lower resistivity values compared to argon-sputtered lines. There is a clear separation between curve 400 and curve 500 throughout the entire probability range, suggesting a consistent resistivity benefit for krypton sputtering across all measured lines. Both curve 400 and curve 500 have a similar S-shaped profile, characteristic of cumulative distribution functions for normally distributed data. This suggests that the line resistivity values for both deposition conditions follow approximately normal distributions. The slopes of curve 400 and curve 500 appear similar, indicating comparable variability in resistivity for both deposition conditions. If one curve were significantly steeper, it could suggest less variability in that condition.

The resistivity value at the 0.5 cumulative probability point (median) is noticeably lower for the krypton-sputtered lines (curve 400) compared to the argon-sputtered lines (curve 500). The separation between curve 400 and curve 500 is maintained at both low and high cumulative probabilities, suggesting that the resistivity benefit of krypton sputtering applies to both the best-performing (low resistivity) and worst-performing (high resistivity) lines.

The clear leftward shift of curve 400 (the krypton-sputtered curve) demonstrates a consistent and significant reduction in line resistivity across the entire population of measured lines. This statistical representation agrees with FIG. 13 and provides additional insight into the distribution of resistivity values. The results suggest benefits of using krypton as the sputtering gas for reducing resistivity in narrow ruthenium interconnect lines, which is advantageous for improving the performance of advanced semiconductor devices.

FIG. 15 illustrates a process flow chart diagram of a method 700 for forming a low resistivity ruthenium film, in accordance with some embodiments. In step 702, a plasma processing chamber having mTorr process pressure capability and/or capability of 400° C. stage temperature is provided, as described above with respect to FIG. 1. In step 704, low ionization working gas species (such as krypton, xenon, or radon) are flowed into the plasma processing chamber, as described above with respect to FIG. 1. In step 706, the low ionization working gas species is excited to generate a stable plasma and power to a ruthenium sputter target, as described above with respect to FIG. 1. In step 708, a ruthenium film is deposited by sputtering in a low ionization gas plasma in the plasma processing chamber, as described above with respect to FIG. 1. The ruthenium film may be deposited to a thickness in a range of 200 Å to 800 Å.

FIG. 16 illustrates a process flow chart diagram of a method 800 for semiconductor manufacturing, in accordance with some embodiments. In step 802, a substrate is provided into a plasma processing chamber, as described above with respect to FIG. 1. In step 804, a ruthenium layer is formed over the substrate with a physical vapor deposition using a sputtering gas comprising krypton or xenon, as described above with respect to FIG. 1. The physical vapor deposition is performed at a substrate temperature of less than 100° C. In step 806, a ruthenium feature is formed from the ruthenium layer with a subtractive process, as described above with respect to FIG. 4.

FIG. 17 illustrates a process flow chart diagram of a method 900 for metal deposition, in accordance with some embodiments. In step 902, a substrate is provided into a physical vapor deposition (PVD) processing chamber, as described above with respect to FIG. 1. The PVD processing chamber comprises a substrate holder for supporting the substrate and multiple sputtering targets comprising ruthenium metal. The multiple sputtering targets are at oblique angles to a top surface of the substrate.

In step 904, a ruthenium metal layer is sputtered onto the substrate with a plasma excitation of a noble gas comprising krypton or xenon at a first substrate temperature of less than 100° C., as described above with respect to FIG. 1. In step 906, the ruthenium metal layer is heat-treated at a second substrate temperature of 400° C. or less, as described above with respect to FIG. 1.

FIG. 18 illustrates a process flow chart diagram of a method 1000 for forming a conductive feature, in accordance with some embodiments. In step 1002, a substrate is provided onto a substrate holder of a plasma sputtering chamber, as described above with respect to FIG. 1. The substrate has a top surface comprising a dielectric layer, as described above with respect to FIG. 2. In step 1004, a ruthenium metal layer is sputtered onto the dielectric layer using a plasma excitation of a noble gas comprising krypton, xenon, or radon, as described above with respect to FIG. 1. The dielectric layer has a temperature of less than 100° C.

In step 1006, the ruthenium metal layer is heated to a temperature of 400° C. or less, as described above with respect to FIG. 1. In step 1008, a ruthenium line is formed from the ruthenium metal layer, as described above with respect to FIG. 4. The ruthenium line has a width of 10 nm or less.

Example embodiments of the disclosure are summarized here. Other embodiments can also be understood from the entirety of the specification as well as the claims filed herein.
Example 1. A method for semiconductor manufacturing, the method including: providing a substrate into a plasma processing chamber; forming a ruthenium layer over the substrate with a physical vapor deposition using a sputtering gas including krypton or xenon, the physical vapor deposition being performed at a substrate temperature of less than 100° C.; and forming a ruthenium feature from the ruthenium layer with a subtractive process.
Example 2. The method of example 1, further including heat-treating the ruthenium layer at a temperature up to 400° C.
Example 3. The method of one of examples 1 or 2, where the ruthenium feature has a width of 10 nm or less.
Example 4. The method of one of examples 1 to 3, where the sputtering gas consists essentially of krypton.
Example 5. The method of one of examples 1 to 3, where the sputtering gas consists essentially of xenon.
Example 6. The method of one of examples 1 to 3, where the sputtering gas consists essentially of a combination of argon and another noble gas.
Example 7. The method of example 6, where the another noble gas is krypton.
Example 8. The method of example 6, where the another noble gas is xenon.
Example 9. The method of one of examples 1 to 3, where the sputtering gas consists essentially of a combination of krypton and xenon.
Example 10. A method for metal deposition, the method including: providing a substrate into a physical vapor deposition (PVD) processing chamber, the PVD processing chamber including a substrate holder for supporting the substrate and multiple sputtering targets including ruthenium metal, the multiple sputtering targets being at oblique angles to a top surface of the substrate; sputtering a ruthenium metal layer onto the substrate with a plasma excitation of a noble gas including krypton or xenon at a first substrate temperature of less than 100° C.; and heat-treating the ruthenium metal layer at a second substrate temperature of 400° C. or less.
Example 11. The method of example 10, where the first substrate temperature is less than 50° C.
Example 12. The method of one of examples 10 or 11, where the first substrate temperature is room temperature.
Example 13. The method of one of examples 10 to 12, where the noble gas consists essentially of krypton.
Example 14. The method of one of examples 10 to 12, where the noble gas consists essentially of xenon.
Example 15. The method of one of examples 10 to 14, further including forming a ruthenium metal line from the ruthenium metal layer with a subtractive process, the ruthenium metal line having a width of 10 nm or less.
Example 16. The method of one of examples 10 to 15, where the ruthenium metal layer has a thickness in a range of 200 Å to 800 Å.
Example 17. A method for forming a conductive feature, the method including: providing a substrate onto a substrate holder of a plasma sputtering chamber, the substrate having a top surface including a dielectric layer; sputtering a ruthenium metal layer onto the dielectric layer using a plasma excitation of a noble gas including krypton, xenon, or radon, the dielectric layer having a temperature of less than 100° C.; heating the ruthenium metal layer to a temperature of 400° C. or less; and forming a ruthenium line from the ruthenium metal layer, the ruthenium line having a width of 10 nm or less.
Example 18. The method of example 17, where the noble gas is free of argon.
Example 19. The method of one of examples 17 or 18, where the ruthenium line has a thickness in a range of 200 Å to 800 Å.
Example 20. The method of one of examples 17 to 19, where the noble gas consists essentially of krypton.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

1. A method for semiconductor manufacturing, the method comprising:
providing a substrate into a plasma processing chamber;
forming a ruthenium layer over the substrate with a physical vapor deposition using a sputtering gas comprising krypton or xenon, the physical vapor deposition being performed at a substrate temperature of less than 100° C.;
heat-treating the ruthenium layer at a temperature up to 400° C. with an anneal performed with a gas; and
forming a ruthenium metal line from the ruthenium layer with a subtractive process.

2. (canceled)

3. The method of claim 1, wherein the ruthenium feature has a width of 10 nm or less.

4. The method of claim 1, wherein the sputtering gas consists essentially of krypton.

5. The method of claim 1, wherein the sputtering gas consists essentially of xenon.

6. The method of claim 1, wherein the sputtering gas consists essentially of a combination of argon and another noble gas.

7. The method of claim 6, wherein the another noble gas is krypton.

8. The method of claim 6, wherein the another noble gas is xenon.

9. The method of claim 1, wherein the sputtering gas consists essentially of a combination of krypton and xenon.

10. A method for metal deposition, the method comprising:
providing a substrate into a physical vapor deposition (PVD) processing chamber, the PVD processing chamber comprising a substrate holder for supporting the substrate and multiple sputtering targets comprising ruthenium metal, the multiple sputtering targets being at oblique angles to a top surface of the substrate;
sputtering a ruthenium metal layer onto the substrate with a plasma excitation of a noble gas comprising krypton or xenon at a first substrate temperature of less than 100° C.;
heat-treating the ruthenium metal layer at a second substrate temperature of 400° C. or less with a heater in the substrate holder; and
forming a ruthenium metal line from the ruthenium metal layer with a subtractive process, the ruthenium metal line being part of an interconnect layer.

11. The method of claim 10, wherein the first substrate temperature is less than 50° C.

12. The method of claim 10, wherein the first substrate temperature is room temperature.

13. The method of claim 10, wherein the noble gas consists essentially of krypton.

14. The method of claim 10, wherein the noble gas consists essentially of xenon.

15. The method of claim 10, wherein the ruthenium metal line has a width of 10 nm or less.

16. The method of claim 10, wherein the ruthenium metal layer has a thickness in a range of 200 Å to 800 Å.

17. A method for forming an interconnect layer, the method comprising:
providing a substrate onto a substrate holder of a plasma sputtering chamber, the substrate having a top surface comprising a dielectric layer;
sputtering a ruthenium metal layer onto the dielectric layer using a plasma excitation of a noble gas comprising krypton, xenon, or radon, the dielectric layer having a temperature of less than 100° C.;
heating the ruthenium metal layer to a temperature of 400° C. or less; and
forming a ruthenium line from the ruthenium metal layer as part of the interconnect layer, the ruthenium line having a width of 10 nm or less.

18. The method of claim 17, wherein the noble gas is free of argon.

19. The method of claim 17, wherein the ruthenium line has a thickness in a range of 200 Å to 800 Å.

20. The method of claim 17, wherein the noble gas consists essentially of krypton.

21. The method of claim 1, wherein the anneal is performed with hydrogen gas.
